(19) United States
(12) Patent Application Publication
(10) Pub. No.: US 2012/0138927 A1
(43) Pub. Date: Jun. 7, 2012

(54) SEMICONDUCTOR DEVICE HAVING STACKED STRUCTURE INCLUDING THROUGH-SILICON-VIAS AND METHOD OF TESTING THE SAME

(75) Inventor: Uk-song KANG, Seongnam-si (KR)

(73) Assignee: Samsung Electronics Co., Ltd., Suwon-si (KR)

(21) Appl. No.: 13/312,000

(22) Filed: Dec. 6, 2011

(30) Foreign Application Priority Data
Dec. 6, 2010 (KR) 10-2010-0123476

(51) Int. Cl. H01L 23/00

(52) U.S. Cl. 257/48; 257/E23.002

(57) ABSTRACT

A semiconductor device having a stacked structure including through-silicon-vias (TSVs) and a method of testing the semiconductor device. The semiconductor device includes a first semiconductor layer, one or more second semiconductor layers stacked on the first semiconductor layer, and a plurality of input through-silicon-vias (TSVs) to transmit signals from a plurality of input pads, respectively. In a test mode, a test signal from the plurality of input pads is transmitted through at least two test paths, and the test signal transmitted through each of the test paths is output as a test result with respect to each of the plurality of input TSVs through an output pad.

### CROSS-REFERENCE TO RELATED APPLICATIONS

This application claims the benefit of priority under 35 U.S.C.§119 to Korean Patent Application No. 10-2010-0123476, filed on Dec. 6, 2010, in the Korean Intellectual Property Office, the disclosure of which is incorporated herein in its entirety by reference.

### BACKGROUND OF THE INVENTION

1. Field of the Invention

The present general inventive concept generally relates to a semiconductor device having a stacked structure including through-silicon-vias (TSVs) and a method to test a connection state of the TSVs of the semiconductor device,

2. Description of the Related Art

A multi-chip package (MCP) is a package chip having multiple chips. In an MCP, necessary memories may be combined in applicable products and space efficiency of mobile devices such as mobile phones may be significantly improved.

In a three-dimensional (3D) stacking scheme, which is one method for manufacturing the MCP, multiple chips are stacked in a vertical direction and the multiple chips are interconnected by using TSVs.

In other words, a semiconductor memory device fabricated using the 3D stacking scheme does not require a metal wire for interconnecting chips, thereby allowing miniaturization, acceleration, and power saving. Thus, demand for semiconductor memory devices having better performance has increased.

However, when the multiple chips are stacked three-dimensionally by using the TSVs, some of the TSVs may have defects. In this case, information about the location and type of defects is necessary. However, it is difficult to accurately test the TSVs

### SUMMARY OF THE INVENTION

The present general inventive concept provides a semiconductor device having a circuit capable of measuring a resistance-capacitance (RC) characteristic of a TSV in a semiconductor memory device having a stacked structure, and a method to test the semiconductor device.

Additional aspects and advantages of the present general inventive concept will be set forth in part in the description which follows and, in part, will be obvious from the description, or may be learned by practice of the general inventive concept

The foregoing and/or other features and utilities of the present general inventive concept may be achieved by a semiconductor device including a first semiconductor layer, one or more second semiconductor layers stacked on the first semiconductor layer, and a plurality of input through-silicon-vias (TSVs) to transmit signals from a plurality of input pads, respectively, in which in a test mode, a test signal from the plurality of input pads is transmitted through at least two test paths, and the test signal transmitted through each of the test paths is output as a test result with respect to each of the plurality of input TSVs through an output pad.

The foregoing and/or other features and utilities of the present general inventive concept may also be achieved by a semiconductor device including a first semiconductor layer, one or more second semiconductor layers stacked on the first semiconductor layer, and a plurality of output through-silicon-vias (TSVs) to transmit signals through a plurality of output pads, respectively, in which in a test mode, a test signal from a plurality of input pads is transmitted through at least two test paths, and the test signal transmitted through each of the test paths is output as a test result with respect to each of the plurality of output TSVs through the plurality of output pads.

The foregoing and/or other features and utilities of the present general inventive concept may also be achieved by a semiconductor device including a first semiconductor layer including an input pad to receive a test signal and an output pad to output the test signal, a second semiconductor layer connected to the first semiconductor layer by at least one through-silicon-via (TSV), and a path selecting unit to select at least one of a plurality of paths to transmit the test signal from the input pad to the output pad, wherein the plurality of paths include at least one path electrically insulated from the at least one TSV and at least one path electrically connected to the at least one TSV.

The at least one path electrically connected to the at least one TSV may include at least one path through the at least one TSV, and at least one path that is not through the at least one TSV.

The at least one TSV may include an input TSV to transmit the test signal from the first semiconductor layer to the second semiconductor layer, and a plurality of output TSVs to transmit the test signal from the second semiconductor layer to the first semiconductor layer.

The at least one TSV may include a plurality of input TSVs to transmit the test signal from the first semiconductor layer to the second semiconductor layer, and an output TSV to transmit the test signal from the second semiconductor layer to the first semiconductor layer.

The input pad may receive the test signal from an external test unit and the output pad may output the test signal to the external test unit.

### BRIEF DESCRIPTION OF THE DRAWINGS

Exemplary embodiments of the inventive concept will be more clearly understood from the following detailed description taken in conjunction with the accompanying drawings in which:

These and/or other aspects and advantages of the present general inventive concept will become apparent and more readily appreciated from the following description of the embodiments, taken in conjunction with the accompanying drawings of which:

FIG. 1 is a schematic diagram of a semiconductor device having a stacked structure including a plurality of semiconductor layers;

FIG. 2 is a diagram of an implementation example of the semiconductor device shown in FIG. 1;

FIGS. 3A and 3B are block diagrams of implementation examples of the semiconductor device shown in FIG. 2;

FIG. 4 is a diagram of a portion of a semiconductor device having a stacked structure according to an exemplary embodiment of the present general inventive concept;

FIG. 5 is a circuit diagram of an implementation example of the semiconductor device shown in FIG. 4;

FIG. 6 is a circuit diagram of an overall structure of a semiconductor device according to an exemplary embodiment of the present general inventive concept;

FIG. 7 is a timing diagram of a test signal provided to the semiconductor device shown in FIG. 6;

FIGS. 8A through 8C are waveform diagrams of various control signals for a test operation for the semiconductor device shown in FIG. 6;

FIG. 9 is a graph of an example where a setup time is measured using a test result;

FIG. 10 is a circuit diagram of a semiconductor device having a stacked structure according to another exemplary embodiment of the present general inventive concept;

FIG. 11 is a diagram of a portion of a semiconductor device having a stacked structure according to another exemplary embodiment of the present general inventive concept;

FIG. 12 is a circuit diagram of an implementation example of the semiconductor device shown in FIG. 11;

FIG. 13 is a circuit diagram of an overall structure of a semiconductor device including circuits shown in FIG. 12;

FIGS. 14A through 14C are waveform diagrams of various control signals for a test operation for the semiconductor device shown in FIG. 13;

FIG. 15 is a graph of examples of setup times measured based on test results with respect to output TSVs shown in FIGS. 14A through 14C;

FIG. 16 is a flowchart of a test method for measuring an RC characteristic of a TSV according to an exemplary embodiment of the present general inventive concept;

FIG. 17 is a block diagram of a test system according to an exemplary embodiment of the present general inventive concept;

FIG. 18 is a block diagram of an application example of a single-chip micro computer including a semiconductor memory device of a stacked structure according to the present general inventive concept;

FIGS. 19A through 19C are block diagrams for illustrating an example of signal transmission of a memory controller and a memory device in a semiconductor memory system according to an exemplary embodiment of the present general inventive concept;

FIG. 20 is a block diagram of an application example of an electronic system including a semiconductor memory device of a stacked structure according to the present general inventive concept;

FIG. 21 is a block diagram of a semiconductor device according to an exemplary embodiment of the present general inventive concept; and

FIG. 22 is a block diagram of a semiconductor device according to an exemplary embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

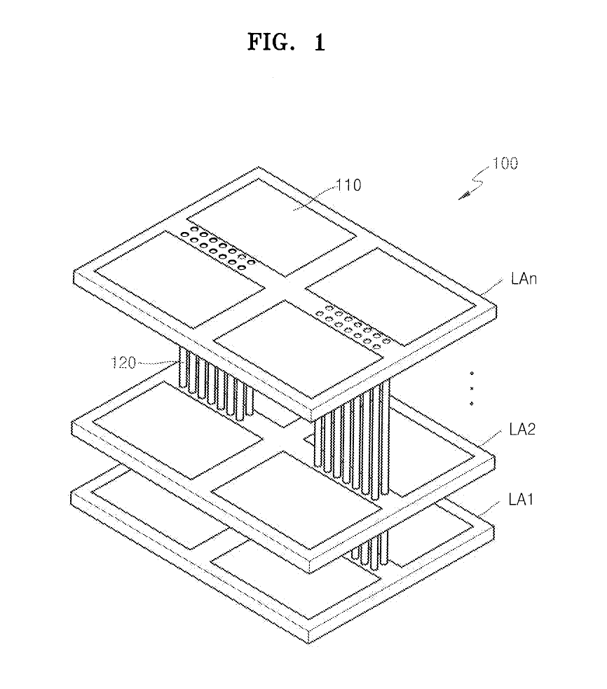

FIG. 1 is a schematic diagram of a semiconductor device having a stacked structure including a plurality of semiconductor layers. Referring to FIG. 1, a semiconductor device 100 includes a plurality of layers LA1 through LAn in a stacked structure, which are interconnected by through-silicon-vias (TSVs) 120. Each of the layers LA1 through LAn includes a plurality of circuit blocks 110 to implement functions of the semiconductor device 100. The semiconductor device 100 may be a semiconductor memory device including memory cells, and in this case, each of the layers LA1 through LAn may be referred to as a cell layer and the plurality of circuit blocks 110 may include memory blocks.

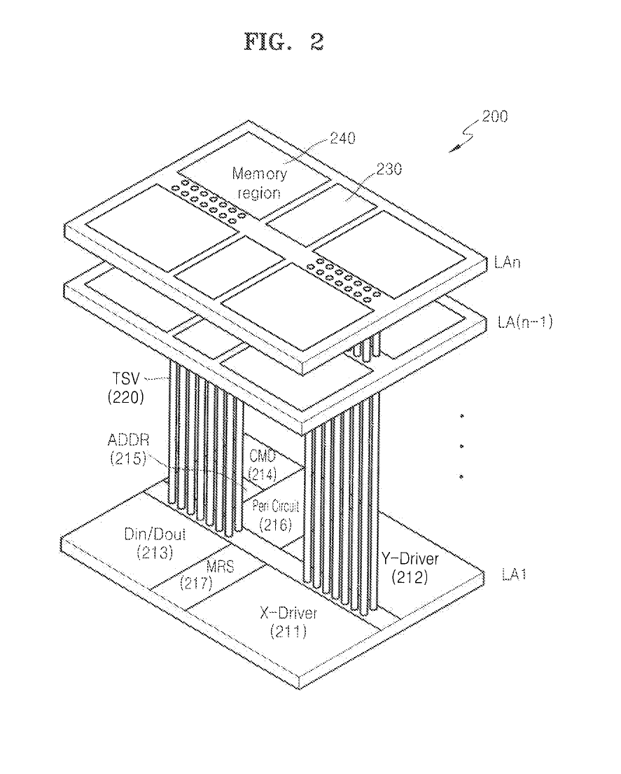

FIG. 2 is a diagram of an implementation example of the semiconductor device 100 shown in FIG. 1. As shown in FIG. 2, a semiconductor device 200 may include multiple semiconductor layers LA1 through LAn. A first semiconductor layer LA1 may be a master chip and the other semiconductor layers LA2 through LAn may be slave chips. The semiconductor layers LA1 through LAn are interconnected by TSVs 220.

The first semiconductor layer LA1 may include various logic circuits to drive a memory. For example, as shown in FIG. 2, the first semiconductor layer LA1 may include an X-driver 211 to drive word lines of the memory, a Y-driver 212 to drive bit lines of the memory, a data input/output unit 213 to control input/output of data, a command buffer 214 to receive, buffer, and decode a command from outside, an address buffer 215 to receive and buffer an address from outside, a mode register set (MRS) 217 to set an operation mode of the memory or to control a test operation mode, and a peripheral circuit 216 in which other logic circuits such as a voltage generation circuit are arranged.

A slave chip, e.g., an nth semiconductor layer LAn, may include a memory region 240 and a logic region 230. The memory region 240 includes a plurality of memory cells and word lines and bit lines to access the memory. The logic region 230 includes a circuit to drive the memory and a circuit to generate layer-related information.

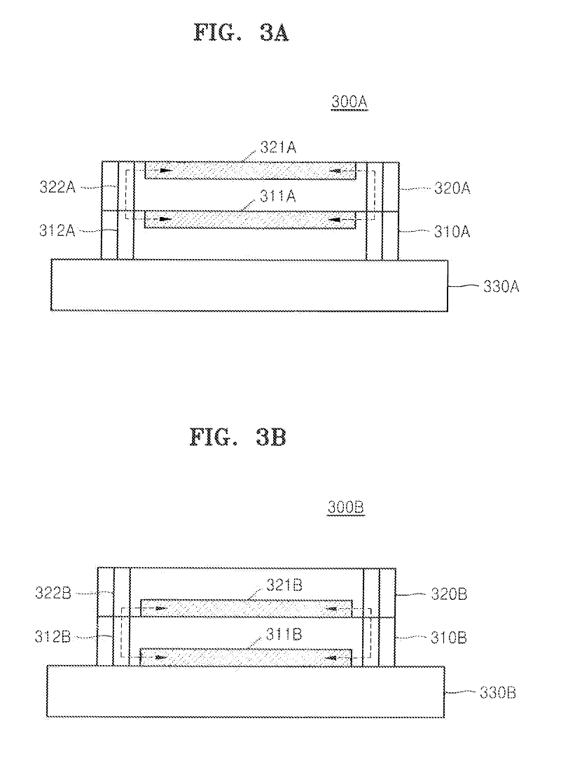

FIGS. 3A and 3B are block diagrams showing implementation examples of the semiconductor device 200 shown in FIG. 2. As shown in FIGS. 3A and 3B, semiconductor devices 300A and 300B each may include a plurality of semiconductor layers and a package substrate for stacking the semiconductor layers thereon. The semiconductor layers each may include an active region where an integrated circuit is disposed and a TSV for electrically connecting the active region with the package substrate. While two semiconductor layers are stacked on the package substrates in FIGS. 3A and 3B, more semiconductor layers may be stacked.

The semiconductor device 300A shown in FIG. 3A has a face-up structure in which active regions 311A and 321A of first and second semiconductor layers 310A and 320A face an opposite side of a package substrate 330A. The semiconductor device 300A includes a TSV 312A disposed in the first semiconductor layer 310A and a TSV 322A disposed in the second semiconductor layer 320A. In this case, the active region 311A of the first semiconductor layer 310A and the active region 321A of the second semiconductor layer 320A transmit and receive signals therebetween through a TSV 322A disposed in the second semiconductor layer 320A,

The semiconductor device 300B shown in FIG. 3B has a face-down structure in which active regions 311B and 321B of first and second semiconductor layers 310B and 320B face a package substrate 330B. The semiconductor device 300B includes a TSV 312B disposed in the first semiconductor layer 310B and a TSV 322B disposed in the second semiconductor layer 320B. In this case, the active region 311B of the first semiconductor device 310B and the active region 321B of the second semiconductor layer 320B transmit and receive signals therebetween through a TSV 312B disposed in the first semiconductor layer 310B.

That is, according to the face-up structure or the face-down structure, a position of a TSV which electrically connects a first semiconductor layer and a second semiconductor layer may differ.

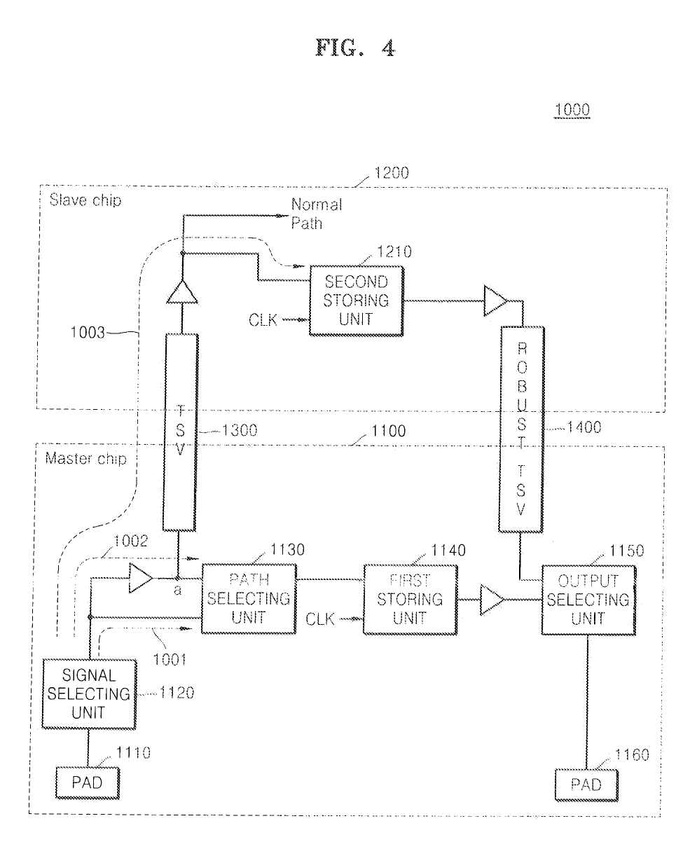

FIG. 4 is a diagram of a portion of a semiconductor device of a stacked structure according to an embodiment of the present general inventive concept. A semiconductor device 1000 may include a first semiconductor layer 1100 and a second semiconductor layer 1200, and TSVs 1300 and 1400 to transmit signals between the first semiconductor layer 1100 and the second semiconductor layer 1200 may be provided in the semiconductor device 1000. The TSV 1300 is an input TSV to transmit a signal into the semiconductor device 1000 from outside, and the other TSV 1400 is an output TSV to transmit a signal from the semiconductor device 1000 to the outside. Although two semiconductor layers 1100 and 1200 are shown in FIG. 4, more semiconductor layers may be provided. The first semiconductor layer 1100 may be a master chip and the second semiconductor layer 1200 may be a slave chip.

In a normal mode, a signal from outside is input through an input pad 1110 and the input signal is transmitted to the first semiconductor layer 1100 and the semiconductor layer 1200. The input signal from the outside may be any one of data, a command/address, and a clock signal, and the input signal is transmitted to an upper-stacked semiconductor layer (e.g., the second semiconductor layer) through one or more buffers and the input TSV 1300.

In a test mode of the semiconductor device 1000, a test signal is input through the input pad 1110 to test an RC characteristic of the input TSV 1300. The test signal is transmitted through at least two paths in the semiconductor device 1000 and is then output through an output pad 1160. The at least two paths may include a path electrically connected with the input TSV 1300 through a node and/or a path for transmission through the input TSV 1300. By measuring variations in a delay time and a data setup time of the output test results when the test signal is transmitted through at least two paths in the semiconductor device 1000, the RC characteristic of the input TSV 1300 may be tested.

The first semiconductor layer 1100 may include a signal selecting unit 1120 which receives a normal signal or a test signal through the input pad 1110 and selectively outputs the signal according to an operation mode (e.g., the normal mode or the test mode), a path selecting unit 1130 which selects one of the at least two paths for transmission of the test signal, and a first storing unit 1140 which stores the test signal output from the path selecting unit 1130. The first semiconductor layer 1100 may further include an output selecting unit 1150 which selects a test signal to be transmitted to the output pad 1160 between the test signal transmitted from the second semiconductor layer 1200 and the test signal output from the first storing unit 1140. The test signal from the second semiconductor layer 1200 may be transmitted through the output TSV 1400, and to reduce an influence of signal transmission through the output TSV 1400, the output TSV 1400 may be a TSV group including two or more TSVs.

The second semiconductor layer 1200 includes a second storing unit 1210 which stores the test signal transmitted through the input TSV 1300. In addition, one or more buffers for signal transmission may be provided in the first semiconductor layer 1100 and the second semiconductor layer 1200, respectively.

The signal selecting unit 1120, the path selecting unit 1130, the first storing unit 1140, and the second storing unit 1210 shown in FIG. 4 may be arranged to correspond to the input TSV 1300. For example, when the semiconductor device 1000 includes multiple input TSVs 1300, the signal selecting unit 1120, the path selecting unit 1130, the first storing unit 1140, and the second storing unit 1210 are arranged to correspond to the input TSVs 1300, respectively. The TSVs 1300 and 1400 may be TSVs disposed on the first semiconductor layer 1100 or the second semiconductor layer 1200, and for example, when the semiconductor layers 1100 and 1200 have a face-down structure, the TSVs 1300 and 1400 may be disposed on the first semiconductor layer 1100.

In the normal mode of the semiconductor device 1000, a signal input through the input pad 1110 is transmitted to the first semiconductor layer 1100 or the second semiconductor layer 1200 through a normal path. On the other hand, in the test mode of the semiconductor device 1000, a test signal input through the input pad 1110 is transmitted through multiple test paths. For example, the multiple test paths may include first through third test paths. The first test path is a path 1001 formed in the first semiconductor layer 1100 and electrically insulated from the input TSV 1300, the second test path is a path 1002 formed in the first semiconductor layer 1100 and electrically connected with the input TSV 1300 through a node a, and the third test path may be a path 1003 to transmit the test signal to the second semiconductor layer 1200 through the input TSV 1300.

First, the test signal input through the input pad 1110 is provided to the path selecting unit 1130 through the first test path 1001 and the second test path 1002. The path selecting unit 1130 selectively outputs a signal transmitted through the first test path 1001 (which hereinafter, will be referred to as a first signal) to the first storing unit 1140. The first storing unit 1140 receives or outputs a signal in response to a clock signal CLK, and receives the first signal from the path selecting unit 1130 and provides the same to the output selecting unit 1150. The output selecting unit 1150 outputs the first signal as a test result through the output pad 1160, and an external device (e.g., a test device, not shown) may analyze a setup time of a signal by using the test result. The first path 1001 is a path electrically insulated from the input TSV 1300, and a variation in a path delay time which basically exists for each input TSV 1300 regardless of the RC characteristic of the input TSV 1300 may be measured.

Thereafter, the path selecting unit 1130 selectively outputs a signal transmitted through the second test path 1002 (which hereinafter, will be referred to as a second signal) to the first storing unit 1140. The first storing unit 1140 provides the second signal to the output selecting unit 1150 in response to the clock signal CLK. The output selecting unit 1150 outputs the second signal as a test result through the output pad 1160, and an external device (e.g., a test device, not shown) may analyze a setup time of a signal by using the test result. The second test path 1002 is a path electrically connected with the input TSV 1300, and the test signal output through the second path 1002 is affected by a capacitance component of the input TSV 1300. Thus, by analyzing the test result provided through the second test path 1002, an influence of the capacitance component of the input TSV 1300 may be measured.

The output selecting unit 1150 selectively outputs a signal transmitted through the third test path 1003 (which hereinafter, will be referred to as a third signal) as a test result through the output pad 1160. The third signal is provided to the output selecting unit 1150 through the second storing unit 1210 and the output TSV 1400. The output selecting unit 1150 may simultaneously receive the first signal or the second signal in the first semiconductor layer 1100 and the third signal from the second semiconductor layer 1200, and selectively output one of them. The third test path 1003 is a path through the input TSV 1300, and the test signal output through the third path 1003 is affected by the capacitance component and a resistance component of the input TSV 1300. By analyzing the test result provided through the third test path 1003, an influence of the capacitance component and the resistance component of the input TSV 1300 may be measured.

FIG. 4 provides an example of a case where the process is performed sequentially through the first test path through the third test path, however, the embodiment of the present general inventive concept is not necessarily limited thereto. For example, an order of selecting test paths may be set arbitrarily. In addition, to measure only the capacitance component of the input TSV 1300, only the test results provided through the first test path 1001 and the second test path 1002 may be analyzed, and to measure only the resistance component of the input TSV 1300, only the test results provided through the first test path 1001 and the third test path 1003 may be analyzed.

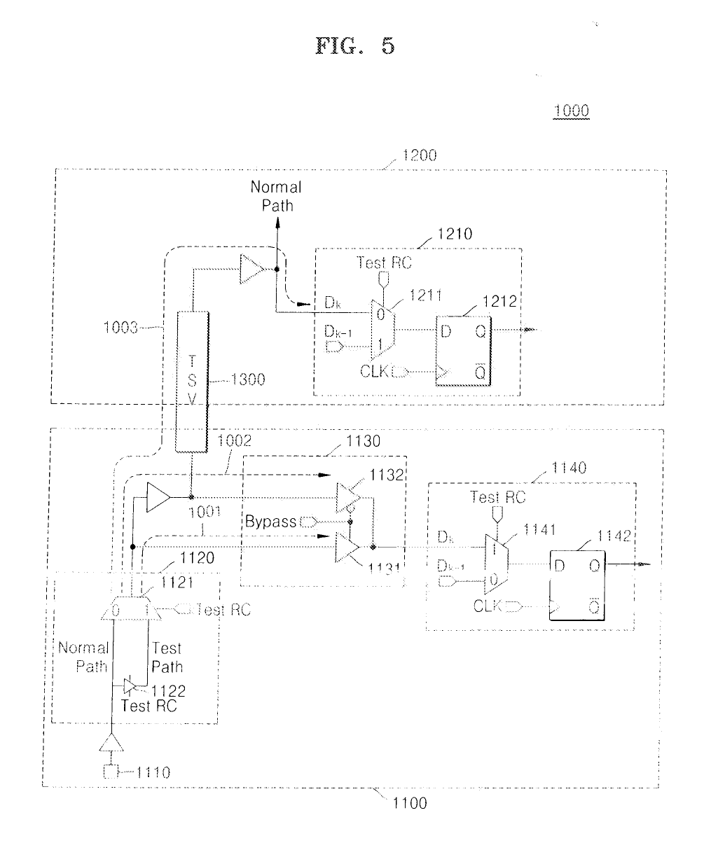

FIG. 5 is a circuit diagram of an example which implements the semiconductor device 1000 shown in FIG. 4. Referring to FIGS. 4 and 5, the semiconductor device 1000 may include the first semiconductor layer 1100 and the second semiconductor layer 1200. The first semiconductor layer 1100 may include the input pad 1110 which receives the normal signal or the test signal from outside, the signal selecting unit 1120 which selectively outputs the normal signal or the test signal, the path selecting unit 1130 which receives the signal through at least two test paths and selectively outputs one of them, and the first storing unit 1140 which stores the signal provided through the selected test path, The second semiconductor layer 1200 may include the second storing unit 1210 which stores the test signal transmitted through the input TSV 1300.

A mode register set (not shown) provided in the semiconductor device 1000 may generate various control signals to control an operation in the test mode. For example, a test enable signal Test RC enables entry to a mode to measure the resistance component and the capacitance component of the input TSV 1300. A bypass signal is used as a control signal to select the first test path 1001 or the second test path 1002.

The signal selecting unit 1120 includes a first multiplexer 1121 and a first tri-state buffer 1122. The first tri-state buffer 1122 may control transmission of the test signal by operating in response to the test enable signal Test RC. A logic circuit (not shown) in the first semiconductor layer 1100 may be disposed before the first multiplexer 1121, and upon selection of the normal path, the normal signal is provided to the logic circuit (not shown) or to the second semiconductor layer 1200 through the first multiplexer 1121 and the input TSV 1300. On the other hand, in the test mode, a test path is selected and the first multiplexer 1121 selectively outputs the test signal in response to the test enable signal Test RC.

The path selecting unit 1130 may include a tri-state buffer connected to a bypass signal Bypass to determine a path of a test signal. For example, the path selecting unit 1130 may include a second tit-state buffer 1131 disposed on the first test path 1001 and a third tri-state buffer 1132 disposed on the second test path 1002. The second and third tri-state buffers 1131 and 1132 are controlled by bypass signals Bypass. For example, if the bypass signal Bypass is logic ‘high’, a first test signal is selectively output from the second tri-state buffer 1131, If the bypass signal Bypass is logic ‘low’, a second test signal is selectively output from the third tri-state buffer 1132. The selected test signal is output to the first storing unit 1140.

The first storing unit 1140 may include a second multiplexer 1141 and a first flip-flop 1142. The second multiplexer 1141 selects a test signal Dk output from the path selecting unit 1130 when the test enable signal Test RC is logic ‘high’, and outputs the selected test signal Dk to the first flip-flop 1142. When the test enable signal Test RC is logic ‘low’, the second multiplexer 1141 selects a test signal Dk-1 from a storing unit corresponding to a previous TSV and outputs the selected test signal Dk-1 to the first flip-flop 1142.

The second storing unit 1210 may include a third multiplexer 1211 and a second flip-flop 1212. The third multiplexer 1211 operates in response to the test enable signal Test RC, and selectively outputs the test signal Dk, transmitted through the input TSV 1300, when the test enable signal Test RC is logic ‘high’, to the second flip-flop 1212. When the test enable signal Test RC is logic ‘low’, the third multiplexer 1211 selects the test signal Dk-1 from a storing unit corresponding to a previous TSV and outputs the selected test signal Dk-1 to the second flip-flop 1212.

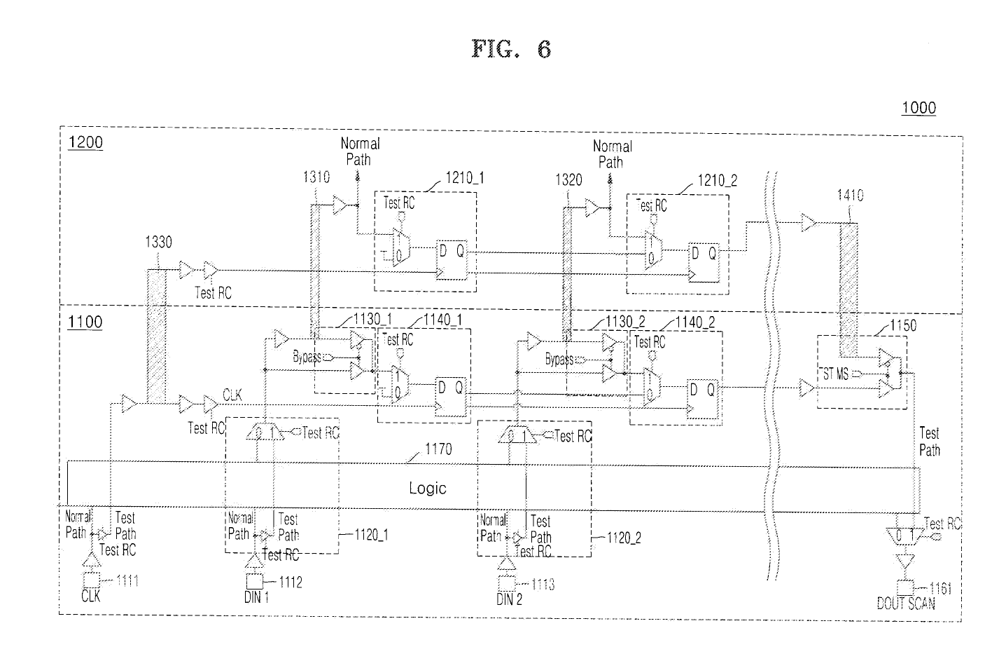

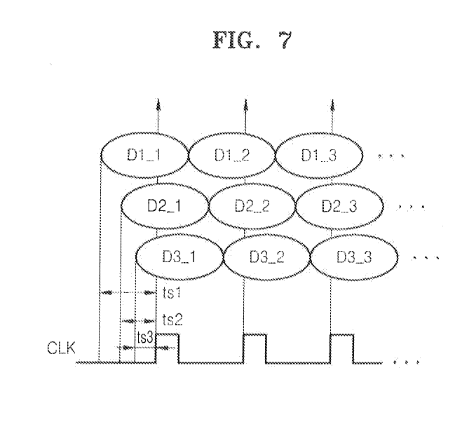

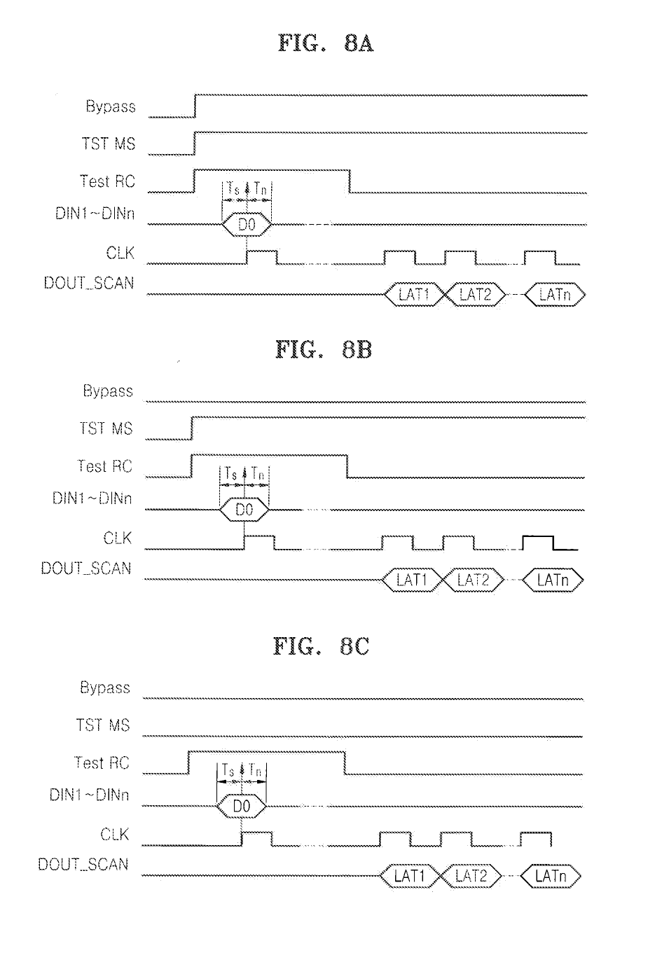

FIG. 6 is a circuit diagram of an overall structure of a semiconductor device according to an embodiment of the present general inventive concept, Referring to FIG. 6, in the semiconductor device 1000, multiple input TSVs may be necessary for transmission of data, addresses, and commands between the first semiconductor layer 1100 and the second semiconductor layer 1200. According to the current embodiment of the present general inventive concept, to measure RC characteristics of the multiple input TSVs, the same or similar circuit blocks as the circuit blocks shown in FIG. 5 may be disposed corresponding to each input TSV. As illustrated in FIG. 6, two input TSVs 1310 and 1320 are shown. However, the present general inventive concept is not limited thereto, and more than two input TSVs may be provided.

Multiple pads are disposed on the first semiconductor layer 1100, and for example, a clock signal CLK to store and output a test signal is input through an input pad 1111, and one or more normal signals or test signals are received through input pads 1112 and 1113. Test results from the first semiconductor layer 1100 and the second semiconductor layer 1200 are output through an output pad 1161.

The clock signal CLK is transmitted into the first semiconductor layer 1100, and then into the second semiconductor layer 1200 through a first TSV group 1330. In the normal mode, a normal path is selected, and a normal signal (e.g., a signal such as data or command/address) is provided to a logic circuit 1170 of the first semiconductor layer 1100 or to the second semiconductor layer 1200 through the input TSVs 1310 and 1320. In the test mode, a test path is selected, and a test signal is transmitted through at least two test paths in the semiconductor device 1000. The signal transmitted through the test path is output as a test result through the output pad 1161.

To conduct a test with respect to the input TSVs 1310 and 1320, various circuit blocks are disposed. For example, to test the first input TSV 1310, a signal selecting unit 1120_1, a path selecting unit 1130_1, a first storing unit 1140_1, and a second storing unit 1210_1 are disposed, and to test the second input TSV 1320, a signal selecting unit 1120_2, a path selecting unit 1130_2, a first storing unit 1140_2, and a second storing unit 1210_2 are disposed. The output selecting unit 1150 receives the test signal in the first semiconductor layer 1100 and the test signal from the second semiconductor layer 1200, and selectively outputs the received test signal. The test signal from the second semiconductor layer 1200 may be provided to the output selecting unit 1150 through a second TSV group 1410. Each of the first TSV group 1330 and the second TSV group 1410 may include multiple TSVs to deal with electrical disconnection in signal transmission.

In the test mode of the semiconductor device 1000, upon reception of the test signal at the same time through the input pads 1112 and 1113, the received test signal is transmitted through multiple test paths. For example, the test signal may be transmitted through a first test path which is formed in the first semiconductor layer 1100 and electrically insulated from the input TSVs 1310 and 1320, a second test path which is formed in the first semiconductor layer 1100 and electrically connected to nodes of the input TSVs 1310 and 1320, and a third test path TSV to transmit to the second semiconductor layer 1200 through the input TSVs 1310 and 1320.

For example, when the test enable signal Test RC goes to the logic ‘high’ level, the test mode starts. The test signal is received through the input pads 1112 and 1113, and the path selecting units 1130_1 and 1130_2 receive a first signal transmitted through the first test path and a second signal transmitted through the second test path. The path selecting units 1130_1 and 1130_2 selectively output the first signal, which is then stored in the first storing units 1140_1 and 1140_2.

Thereafter, when the test enable signal Test RC becomes logic ‘low’, the first signal stored in the first storing units 1140_1 and 1140_2 is provided to the outside in synchronization with the clock signal CLK. The first signal stored in the first storing units 1140_1 and 1140_2 may be transmitted and provided to the outside according to a shift register scheme. For example, a first signal stored in a first storing unit corresponding to a first TSV may be provided to a first storing unit corresponding to a second TSV. As shown in FIG. 6, the first signal stored in the first storing unit 1140_1 corresponding to the first input TSV 1310 may be provided to the first storing unit 1140_2 corresponding to the second input TSV 1320, Thus, the first signals passing through the first test path corresponding to each of the multiple input TSVs 1310 and 1320 are sequentially output to outside through the output pad 1161.

The foregoing transmission of the test signal through the first test path is repeated. For example, by inputting the test signal after a predetermined delay time, the test operation is repeated, or by inputting the clock signal CLK after a predetermined delay time, the test operation is repeated. By referring to the results of the repeated tests, a normal pass or fail of a signal may be determined, and by using the determination result, a setup time or a hold time of the signal excluding the RC characteristics of the multiple input TSVs 1310 and 1320 may be calculated.

Thereafter, for the second test path and the third test path, the test results are output in the same manner as described above. By analyzing the test results, a setup time or a hold time for each of the second test path and the third test path is calculated. By comparing the setup times or hold times calculated for the first through third test paths, the RC characteristics of the input TSVs 1310 and 1320 are determined. The third signals passing through the third test path are transmitted to the second semiconductor layer 1200 through the first TSV group 1330.

FIG. 7 is a timing diagram of a test signal provided to the semiconductor device 1000 shown in FIG. 6. A test method for a TSV according to the inventive concept may be performed by measuring a setup time or hold time of a signal for each of the multiple input TSVs 1310 and 1320. The setup time refers to a time for which a signal (e.g., an address, a command, or data) has to be input through an input pad before an external clock signal CLK. Thus, to measure the setup time, the test signal is repeatedly provided through the input pad with different offset times from an external clock signal CLK, until a failure occurs, thereby repeating the test operation.

In FIG. 7, the test signal is repeatedly provided through any one test path, and the setup time for the corresponding test path is measured, Referring to FIG. 7, an offset time is first set to ts1, and test signals D1_1, D2_1, and D3_1 are provided through a plurality of input pads. The test signals D1_1, D2_1, and D3_are transmitted through multiple test paths and output through an output pad. By analyzing the output test result, a fail or pass is determined.

Thereafter, an offset time is set to ts2, and test signals D1_2, D2_2, and D3_2 are provided through a plurality of input pads. An offset time is then set to ts3 and test signals D1_3, D2_3, and D3_3 are provided. An offset time just prior to when the output test result first corresponds to a failure may be defined as a setup time. The offset times ts1, ts2, and ts3 may be arranged in a descending order. For example, offset time ts1 may be greater than offset time ts2 and offset time ts2 may be greater than offset time ts3.

In other words, the setup time is measured while moving a relative position of the clock signal with respect to the test signal, and the signal stored in the signal storing unit for each of the multiple test paths is output through a separate test path, such that the setup times for respective test paths are determined by a test device (not shown).

FIGS. 8A through 8C are waveform diagrams of various control signals for the test operation for the semiconductor device 1000 shown in FIG. 6. To determine the RC characteristics of the multiple input TSVs 1310 and 1320, the setup times or hold times are measured. When the setup time is a time during which an address, a command, or data has to be input before the external clock signal CLK, the hold time is a time during which the signals have to be maintained based on the external clock signal CLK. For example, when the setup time and the hold time are 2 ns and 1 ns, respectively, the signal has to be provided 2 ns before from the external clock signal CLK and the provided signal has to be maintained for 1 ns or more from the external clock signal CLK.

FIG. 8A is a portion of a signal waveform diagram corresponding to the first test path electrically insulated from the input TSVs 1310 and 1320. Referring to FIGS. 6 and 8A, in the path selecting units 1130_1 and 1130_2, a bypass signal Bypass that is logic ‘high’ is provided. A layer selection signal TST MS provided to the output selecting unit 1150 is also maintained to be logic ‘high’.

On the assumption that the number of input pads is n in FIG. 6, a test signal D0 is simultaneously provided to a plurality of input pads DIN1 through DINn when the test enable signal Test RC is logic ‘high’. A clock signal CLK may be provided through input pad 1111 and the timing of the test signal D0 is offset from the clock signal CLK by an offset time. The provided test signal D0 is output sequentially as test results LAT1 through LATn through an output pad DOUT_SCAN 1161.

When the test enable signal Test RC becomes logic ‘low’, the test results LAT1 through LATn are sequentially output through the output pad DOUT_SCAN in synchronization with the clock signal CLK. A pass or fail is determined by analyzing the output test results. A pass may be determined when the test results LAT1 through LATn are synchronized with the clock signal CLK and a failure may be determined when the test results LAT1 through LATn are not synchronized with the clock signal CLK. The test signal D0 may be provided with varying offset times. For example, the test signal D0 may be repeatedly provided with decreasing offset times and the output test results corresponding to each offset time are analyzed. In this case, when the first failure occurs, the offset time that corresponds to the last pass may be defined as the setup time. An accurate setup time may determined in this manner. Alternatively, the test signal D0 may be repeatedly provided with increasing offset times and the output test results corresponding to each offset time are analyzed. In this case, the offset time that corresponds to the first pass may be defined as the setup time. An accurate setup time may also be determined in this manner.

FIG. 8B is a portion of a signal waveform diagram corresponding to the second test path connected with the input TSVs 1310 and 1320 through nodes. Referring to FIGS. 6 and 8B, in the path selecting units 1130_1 and 1130_2, a bypass signal Bypass that is logic ‘low’ is provided. The layer selection signal TST MS provided to the output selecting unit 1150 is also maintained at logic ‘high’. The test enable signal Test RC, and the test signal D0 provided to the input pads DIN1 through DINn may have the same signal waveforms as those shown in FIG. 8A. The test results LAT1 through LATn corresponding to the second test path are output through the output pad DOUT_SCAN. Also for the second test path, by varying the offset time of the test signal D0 and analyzing the output test results as described above, an accurate setup time may be determined.

FIG. 8C is a portion of a signal waveform diagram corresponding to the third test path in which the test signal D0 is transmitted through the input TSVs 1310 and 1320. Referring to FIGS. 6 and 8C, the layer selection signal TST MS provided to the output selecting unit 1150 is maintained to be logic ‘high’. The test enable signal Test RC, the bypass signal Bypass, and the test signal D0 provided to the input pads DIN1 through DINn may have the same waveforms as those shown in FIG. 8B. The test results LAT1 through LATn for the third test path are output through the output pad DOUT_SCAN. For the third test path, by varying the offset time of the test signal D0 and analyzing the output test results as described above, an accurate setup time may be determined.

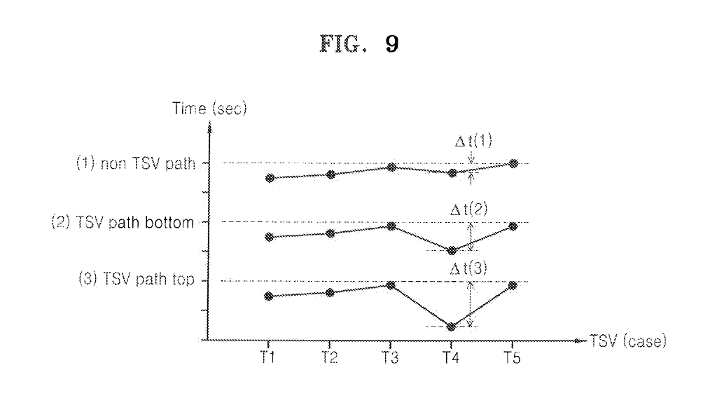

FIG. 9 is a graph of an example where a setup time is measured using a test result. Referring to FIG. 9, a horizontal axis indicates a plurality of input TSVs T1, T2, T3, T4, and T5 mounted in the semiconductor device 1000 and a vertical axis indicates a setup time corresponding to each test path for each input TSV. As illustrated in FIG. 9, the vertical axis includes setup times for a first test path, (1) non TSV path, which is a test path that is electrically insulated from the input TSVs, a second test path, (2) TSV path bottom, which is a test path that is electrically connected to each input TSV, and a third test path, (3) TSV path top, which is a test path through each input TSV. A setup time for a first test path (1) non TSV path is longest, and a setup time for a third test path (3) TSV path top is shortest. This is because, as a transmission path of a signal is longer, a delay time of the signal from input until output becomes longer. When capacitance components of all input TSVs are the same in the second test path, a variation curve of the first test path may be the same or similar to a variation curve of the second test path. When RC characteristics of all input TSVs are the same in the third test path, a variation curve of the first test path may be the same as or similar to a variation curve of the third test path.

However, if a connection state of a particular input TSV is not good, a variation Δt in a setup time for the input TSV may be larger than an average variation. For example, when a connection state of a fourth input TSV T4 is abnormal in the graph shown in FIG. 9, variations Δt(2) and Δt(3) in that state are larger. As such, by measuring a relative change in the setup times between a plurality of input TSVs, an input TSV having an abnormal connection state may be identified.

That is, based on an average setup time in the first test path, measured in the plurality of input TSVs, the setup time and the variation Δt(2) for the second test path are calculated and a capacitance component of the input TSV may be measured by using the calculation result. Likewise, when the setup time and the variation Δt(3) in the third test path are monitored, the RC characteristic including the capacitance component and the resistance component of the input TSV may be monitored. However, if there is a process, voltage, and temperature variation between upper and lower chips, a corresponding error may exist.

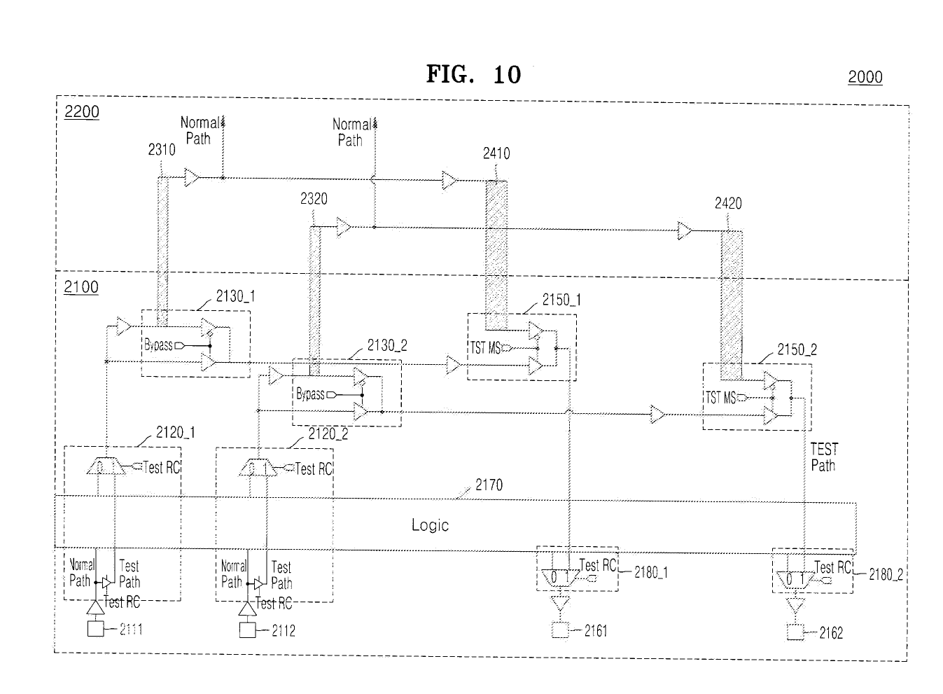

FIG. 10 is a circuit diagram of a semiconductor device of a stacked structure according to another embodiment of the present general inventive concept. Referring to FIG. 10, a semiconductor device 2000 receives a test signal through an input pad and outputs the test signal through an output pad. Since the semiconductor device 2000 does not latch the received test signal, the semiconductor device 2000 does not include separate storing units to store the test signal. Instead, a plurality of output pads are disposed to output test results corresponding to test signals received through a plurality of input pads.

As shown in FIG. 10, the semiconductor device 2000 includes a first semiconductor layer 2100 and a second semiconductor layer 2200. The first semiconductor layer 2100 receives a normal signal or a test signal through input pads 2111 and 2112. The normal signal is transmitted to normal paths through signal selecting units 2120_1 and 2120_2 and input TSVs 2310 and 2320, In the test mode, a test signal is transmitted through at least two test paths, and the transmitted test signal is output as a test result through output pads 2161 and 2162. For the test operation, the first semiconductor layer 2100 may include path selecting units 2130_1 and 2130_2 and output selecting units 2150_1 and 2150_2. While two input TSVs 2310 and 2320 are shown in FIG. 10, more input TSVs may be disposed in the semiconductor device 2000. In addition, a path selecting unit and an output selecting unit are disposed to correspond to each input TSV.

TSV groups 2410 and 2420 shown in FIG. 10 transmit a test signal from the second semiconductor layer 2200 to the first semiconductor layer 2100, and each of them may include a plurality of TSVs. The output pads 2161 and 2162 which output a test result may be pads which output a normal signal in a normal operation or may be test output pads which are selectively used only in the test operation. When the output pads 2161 and 2162 are pads which output a normal signal, the normal signal from the second semiconductor layer 2200 may be provided to the output selecting units 2150_1 and 2150_2 through an additional output TSV (not shown), Selecting units 2180_1 and 2180_2 connected to the output pads 2161 and 2162 of FIG. 10 may selectively output the normal signal or selectively output the test signal.

In the test operation, the test signal is input through the input pads 2161 and 2162 and then transmitted through first through third test paths. The path selecting units 2130_1 and 2130_2 receive a first signal of the first test path and a second signal of the second test path. The path selecting units 2130_1 and 2130_2 provide one of the first signal and the second signal to the output selecting units 2150_1 and 2150_2 in response to the bypass signal Bypass. The third signal provided from the third test path through the input TSVs 2310 and 2320 is provided to the output selecting units 2150_1 and 2150_2. The output selecting units 2150_1 and 2150_2 output the first signal or the second signal or output the third signal in response to the layer selection signal TST MS. The outputs from the output selecting units 2150_1 and 2150_2 are provided as test results to an external test device (not shown) through the output pads 2161 and 2162.

By analyzing the output test results, the setup time is measured to determine RC characteristics of the input TSVs 2310 and 2320. Determination of the RC characteristics may be performed in the same or similar manner as or to that described above, and thus, will not be described in detail.

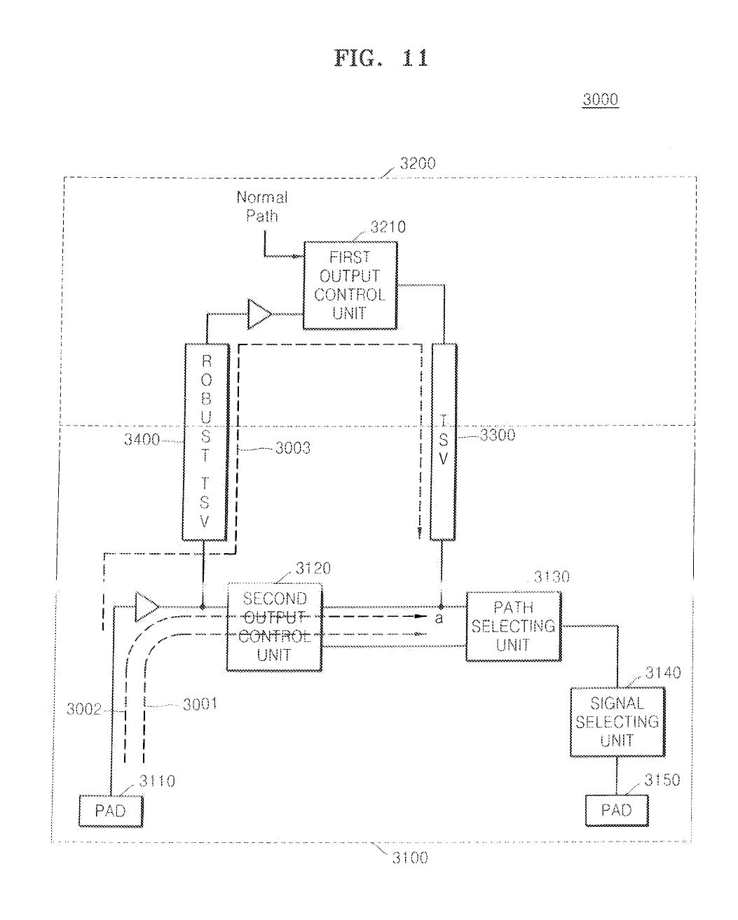

FIG. 11 is a diagram of a portion of a semiconductor device of a stacked structure according to another embodiment of the present general inventive concept. A semiconductor device 3000 includes a first semiconductor layer 3100, a second semiconductor layer 3200, and a TSV 3300 and a TSV group 3400 which connect the two semiconductor layers 3100 and 3200. The first semiconductor layer 3100 may be a master chip and the second semiconductor layer 3200 may be a slave chip. FIG. 11 shows an embodiment where an RC characteristic of an output TSV for transmitting a signal in the semiconductor device 3000 to outside is tested, and thus, the TSV 3300 is assumed to be an output TSV.

In the normal mode, a signal in the semiconductor device 3000 is transmitted to the outside. A signal of the second semiconductor layer 3200 is transmitted to a first output control unit 3210 through the normal path, and is provided to outside through the output TSV 3300, a path selecting unit 3130, and an output pad 3150.

In the test mode of a TSV, a test signal for testing an RC characteristic of the output TSV 3300 is provided and a variation in a setup time of an output value (test result) may be measured.

A basic concept for determining the RC characteristic of the output TSV 3300 is similar to the above-described method for testing an RC characteristic of an input TSV. However, in a test of the RC characteristic of the output TSV 3300, a test result is provided from the semiconductor device 3000 to an external test device (not shown) and a setup time may be determined by using a strobe signal of the test device.

Referring to FIG. 11, the test signal is transmitted through a first test path 3001, which is formed in the first semiconductor layer 3100 and electrically insulated from the output TSV 3300, a second test path 3002, which is formed in the first semiconductor layer 3100 and connected with the output TSV 3300 through a node, and a third test path 3003, which has a transmission path passing through the output TSV 3300.

The first test path 3001 is not electrically connected with the output TSV 3300, and thus a variation in a path delay basically existing in the output TSV 3300 may be measured.

The second test path 3002 is a path which can measure an influence of a capacitance component of the output TSV 3300. The third test path 3003 transmits a test signal through the output TSV 3300, such that an RC characteristic of the output TSV 3300 can be measured,

In the test mode, the test signal is input through the input pad 3110, transmitted through a test path in the first semiconductor layer 3100, and transmitted to the first output control unit 3210 of the second semiconductor layer 3200 through the TSV group 3400. The first output control unit 3210 receives data transmitted through the normal path and the test signal, and selectively outputs the test signal in the test mode. The test signal output from the first output control unit 3210 is transmitted to the path selecting unit 3130 through the output TSV 3300. The path selecting unit 3130 receives the first through third signals transmitted through the first through third test paths, and selectively outputs any one of those signals. The signal output from the path selecting unit 3130, after passing through the signal selecting unit 3140, is provided to outside through the output pad 3150.

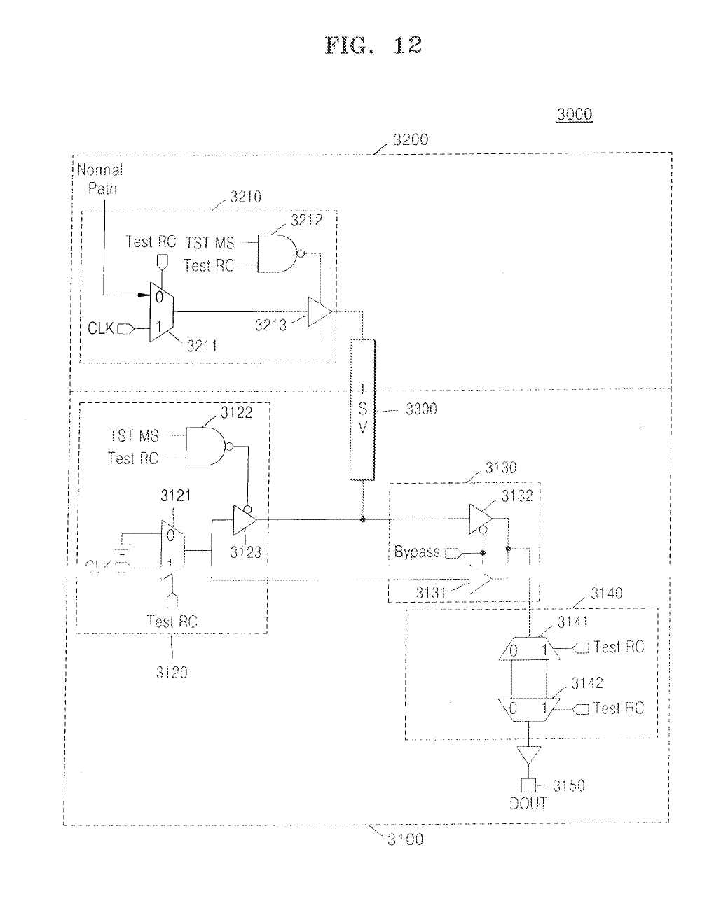

FIG. 12 is a circuit diagram of an implementation example of the semiconductor device shown in FIG. 11. Referring to FIGS. 11 and 12, the semiconductor device 3000 includes the first semiconductor layer 3100, the second semiconductor layer 3200, and the output TSV 3300. The second semiconductor layer 3200 may include the first output control unit 3210 which receives the normal signal transmitted through the normal path and the test signal input through the TSV group 3400 and outputs one of the normal signal and the test signal. The first semiconductor layer 3100 may include a second output control unit 3120, which controls output of the test signal through the first test path and/or the second test path, the path selecting unit 3130, which selects one of the first test path and the second test path, and the signal selecting unit 3140, which selectively outputs the test signal or the normal signal to outside.

A detailed description of the test operation of the semiconductor device 3000 structured as described above may be made as below. In this description, a clock signal CLK input through the input pad 3110 is used as the test signal.

A mode register set (MRS, not shown) may generate various control signals for a test mode operation of the semiconductor device 3000. The test enable signal Test RC enables entry to a measurement mode regarding resistance and capacitance components of the output TSV 3300. The bypass signal Bypass allows selection between the first test path 3001 or the second test path 3002, and the layer selection signal TST MS allows selection between test paths of the first semiconductor layer 3100 and the second semiconductor layer 3200.

The first output control unit 3210 includes a first multiplexer 3211, a first NAND gate 3212, and a first tri-state buffer 3213. The first multiplexer 3211 receives a normal signal generated in the second semiconductor layer 3200 and a test signal (clock signal) for a test operation. The first multiplexer 3211 selects one of the normal signal and the test signal in response to the test enable signal Test RC, and outputs the selected signal to the first tri-state buffer 3213.

The first NAND gate 3212 receives the test enable signal Test RC and the layer selection signal TST MS, performs a NAND operation thereon, and then outputs a NAND operation result to the first tri-state buffer 3213. An on/off connection of the first tri-state buffer 3213 is controlled by an output value of the first NAND gate 3212.

The output TSV 3300 is a connection path of an output signal transmitted from the second semiconductor layer 3200 to the first semiconductor layer 3100. The output TSV 3300 is also electrically connected to the first output control unit 3210, the second output control unit 3120, and the path selecting unit 3130.

The second output control unit 3120 may include a second multiplexer 3121, a second NAND gate 3122, and a second tri-state buffer 3123. The second multiplexer 3121 receives a clock signal CLK as a test signal. According to the test enable signal Test RC, the second multiplexer 3121 outputs the clock signal CLK to the second tri-state buffer 3123. The second NAND gate 3122 receives the test enable signal Test RC and the layer selection signal TST MS, performs a NAND operation thereon, and transmits a NAND operation result to the second tri-state buffer 3123. An on/off connection of the second tri-state buffer 3123 is controlled by an output value of the second NAND gate 3122.

The path selecting unit 3130 includes a third tri-state buffer 3131 and a fourth tri-state buffer 3132, each of which receives the bypass signal Bypass. The first signal passing through the first test path electrically insulated from the output TSV 3300 is provided to the third tri-state buffer 3131. The second signal passing through the second test path electrically connected with the output TSV 3300 through a node and the third signal transmitted through the output TSV 3300 from the second semiconductor layer 3200 are provided to the fourth tri-state buffer 3132. According to a state of the bypass signal Bypass, one of an output signal of the third tri-state buffer 3131 and an output signal of the fourth tri-state buffer 3132 is selected and transmitted to the signal selecting unit 3140.

The signal selecting unit 3140 may include a third multiplexer 3141 and a fourth multiplexer 3142. The third multiplexer 3141 and the fourth multiplexer 3142 select the normal path or the test path in response to the test enable signal Test RC, and provide a selected signal to outside through the output pad 3150.

FIG. 13 is a circuit diagram of an overall structure of a semiconductor device including circuits shown in FIG, 12, Referring to FIGS. 12 and 13, multiple output TSVs may be necessary to output a signal from the semiconductor device 3000 to the outside. As shown in FIG. 13, the semiconductor device 3000 may include multiple output TSVs 3310 and 3320 to output a signal to the outside and a TSV group 3400 to receive a test signal in a test mode.

To test RC characteristics of the multiple output TSVs 3310 and 3320, first output control units 3210_1 and 3210_2, second output control units 3120_1 and 3120_2, path selecting units 3130_1 and 3130_2, and signal selecting units 3140_1 and 3140_2 are provided in the semiconductor device 3000 to correspond to the output TSVs 3310 and 3320, respectively.

The input pad 3110 receives a test signal from outside and transmits the same to the internal TSV group 3400. To deal with electrical disconnection of the test signal, the TSV group 3400 may include multiple TSVs. The test signal may be provided to various circuit blocks in the semiconductor device 3000 through one or more buffers or tri-state buffers. For example, as shown in FIG. 13, transmission of the test signal transmitted through the TSV group 3400 may be controlled by the tri-state buffers which operate according to the test enable signal Test RC.

The test signal is provided to the second output control units 3120_1 and 3120_2 in the first semiconductor layer 3100, which then transmit the first signal and the second signal to the path selecting units 3130_1 and 3130_2 through the first test path and the second test path, respectively.

The test signal may be provided through the TSV group 3400 to the first output control units 3130_1 and 3130_2 of the second semiconductor layer 3200, which then transmit the third signal through the third test path through the output TSVs 3310 and 3320 to path selecting units 3130_1 and 3130_2.

Among the first signal, the second signal, and the third signal received by the path selecting units 3130_1 and 3130_2 through the first test path, the second test path, and the third test path, one test signal is selected according to waveforms of the bypass signal Bypass and the layer selection signal TST MS. The selected test signal, after passing through the signal selecting units 3140_1 and 3140_2, is transmitted to outside through the output pads 3151 and 3152.

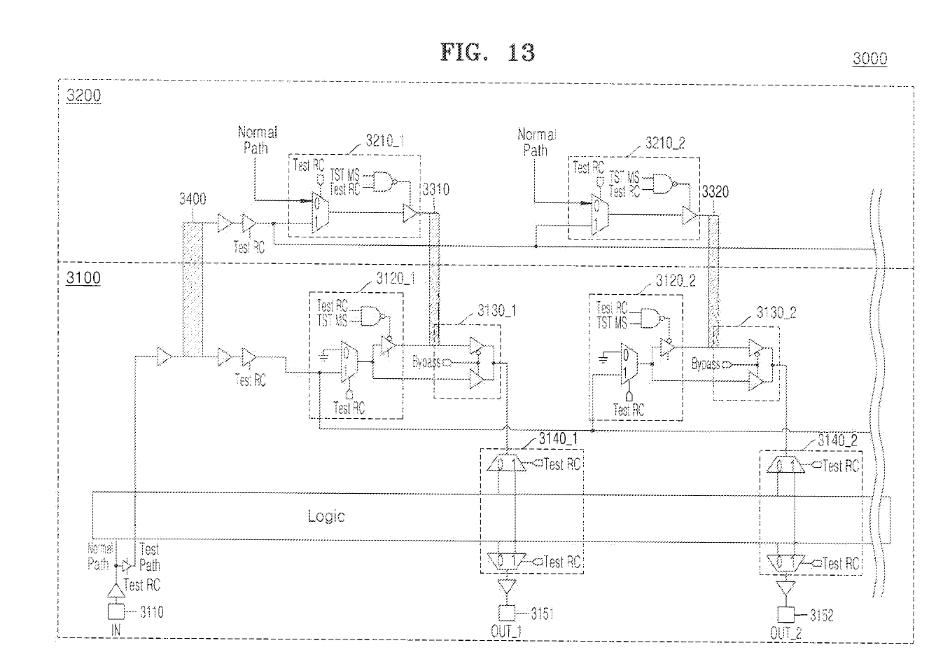

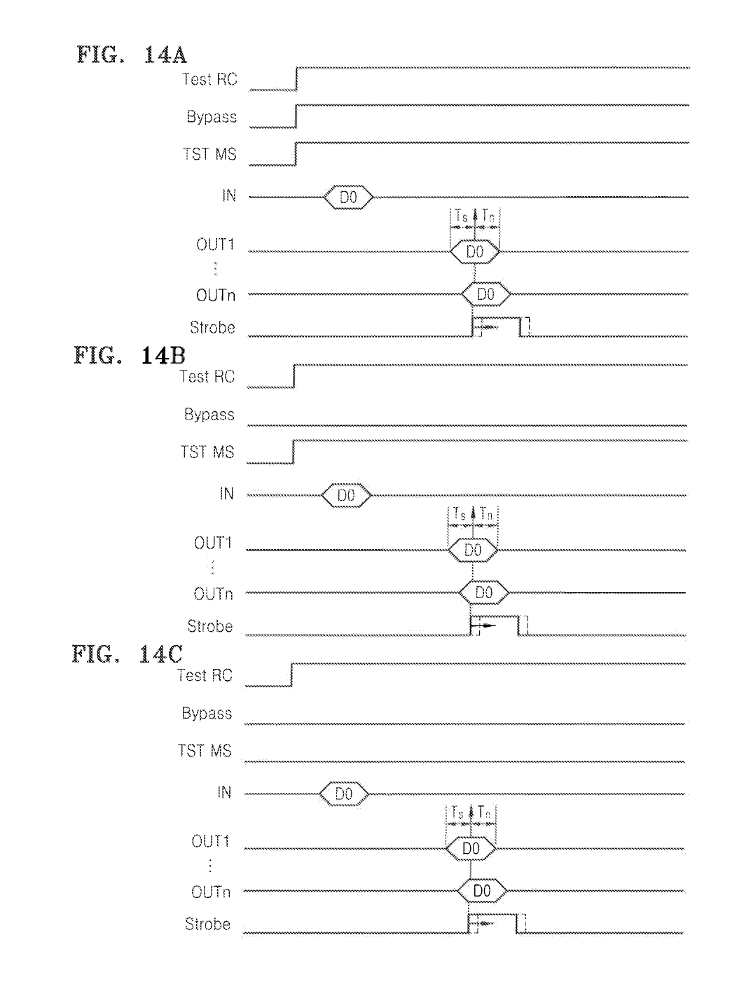

FIGS. 14A through 14C are waveform diagrams of the layer selection signal TST MS, the bypass signal Bypass, the test enable signal Test RC, the clock signal, and input/output signals for the first test path, the second test path, and the third test path shown in FIG. 13.

FIG. 14A is a portion of a signal waveform diagram corresponding to the first test path electrically insulated from the output TSVs 3310 and 3320. Referring to FIGS. 10 through 14A, when the test enable signal Test RC becomes logic ‘high’, the test mode starts. When the test signal D0 is transmitted through the input pad 3110, the layer selection signal TST MS that is logic ‘high’ is provided to the second output control units 3120_1 and 3120_2, and the bypass signal Bypass that is logic ‘high’ is provided to the path selecting units 3130_1 and 3130_2, such that the first test path is selected. On the assumption that the number of TSVs to be tested is n, the test signal D0 transmitted through the first test path is output as a test result through multiple output pads OUT_1 through OUT_n, and a test device (not shown) receives the test result in response to a strobe signal. The test device moves the strobe signal in a direction indicated by the arrow to repeat the test operation several times and analyze the test results, thus measuring setup times of the output TSVs 3310 and 3320 associated with the first test path. That is, the test device varies an offset time between the output test results and the strobe signal, and an offset time of the strobe signal which corresponds to the output test result of an output pad indicates the setup time of the output pad.

FIG. 14B is a portion of a signal waveform diagram corresponding to the second test path connected with the output TSVs 3310 and 3320 through nodes. Referring to FIGS. 10 through 14B, the test enable signal Test RC becomes logic ‘high’, and the test signal D0 is transmitted through the input pad 3110. The layer selection signal TST MS that is logic ‘high’ and the bypass signal Bypass that is logic ‘low’ are provided, such that the second test path is selected. The test signal D0 transmitted through the second test path is output as a test result through the multiple output pads OUT_l through OUT_n. The strobe signal is moved in a direction indicated by the arrow to repeat the test operation, thus measuring the setup times of the output TSVs 3310 and 3320 associated with the second test path.

FIG. 14C is a portion of a signal waveform diagram corresponding to the third test path passing through the output TSVs 3310 and 3320. Referring to FIGS. 10 through 14C, the test enable signal Test RC becomes logic ‘high’ by the MRS, and the test signal D0 is transmitted through the input pad 3110. The layer selection signal TST MS that is logic ‘low’ and the bypass signal Bypass that is logic ‘low’ are provided, such that the third test path is selected. The test signal D0 transmitted through the third test path is output as a test result through the multiple output pads OUT_1 through OUT₁₃ n. The strobe signal is moved in a direction indicated by the arrow to repeat the test operation, thus measuring the setup times of the output TSVs 3310 and 3320 associated with the third test path.

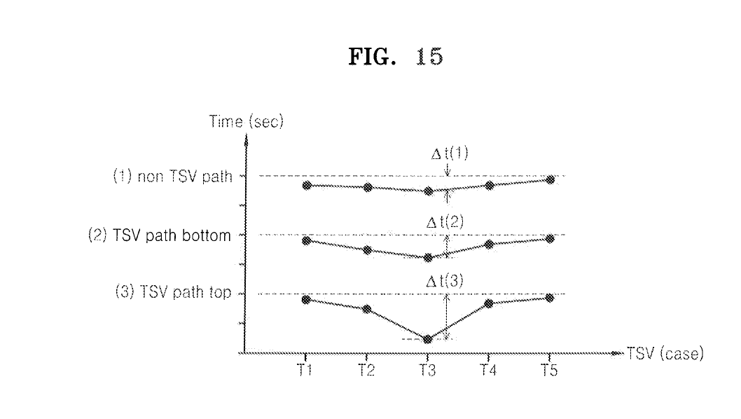

FIG. 15 is a graph of examples of setup times measured based on test results with respect to output TSVs shown in FIGS. 14A through 14C. Referring to FIG. 15, a horizontal axis indicates a plurality of output TSVs T1, T2, T3, T4, and T5 mounted on the semiconductor device 3000, and a vertical axis indicates a setup time according to the test method. A setup time for a first test path (1) non TSV path electrically insulated from the output TSVs 3310 and 3320 is longest, and a setup time for a third test path (3) TSV path top is shortest. When capacitance components of all of the output TSVs 3310 and 3320 in the second test path are the same as each other or RC characteristics of all of the output TSVs 3310 and 3320 in the third test path are the same as each other, a variation curve of the first test path and variation curves of the second and third test paths have the same shape or similar shapes.

However, if a connection state of a particular output TSV is poor, a variation Δt in a setup time of the output TSV may be larger than an average variation. For example, when a connection state of a third output TSV T3 is abnormal in the graph shown in FIG. 15, variations Δt(2) and Δt(3) in that state are larger. As such, by measuring a relative change in the setup times between a plurality of input TSVs, an output TSV having an abnormal connection state may be identified.

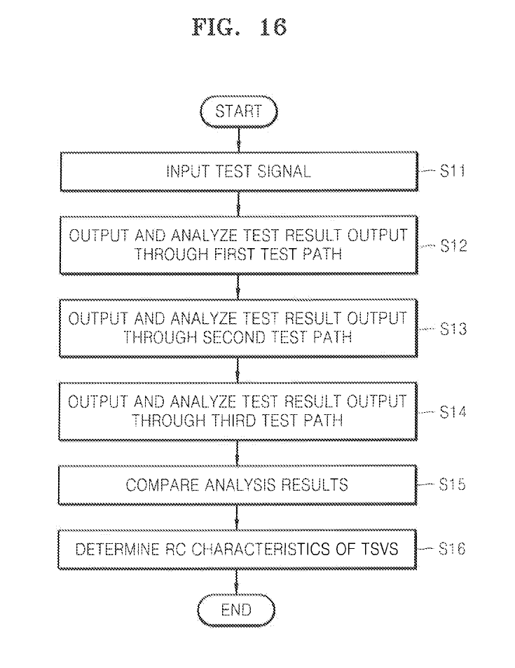

FIG. 16 is a flowchart of a test method for measuring an RC characteristic of a TSV according to an embodiment of the inventive concept. Referring to FIGS. 6, 9, 13, 15, and 16, to determine a RC characteristic of an input TSV or an output TSV of a semiconductor device, a test signal is input through an input pad in operation S11. The test signal input to the semiconductor device is transmitted through multiple test paths (e.g., first through third test paths), and the test signal transmitted through each test path is provided as a test result to an external test circuit through an output pad.

First, first signals transmitted through the first test path, which is formed in a first semiconductor layer and electrically insulated from TSVs, are output as test results, and a test circuit analyzes the test results to measure setup times in operation S12. From the setup times of the first signals, a path delay time basically existing in the TSVs can be determined.

Second signals transmitted through the second test path, which is formed in the first semiconductor layer and electrically connected with TSVs through nodes, are output as test results, and the test circuit analyzes the test results to measure setup times in operation S13. In this case, the second test path is affected by capacitance components of the TSVs through the nodes, and thus, the setup times measured in the second test path are overall smaller than those measured in the first test path. When a capacitance component of a particular TSV is abnormally large, the amount of reduction in a measurement value of a setup time of the TSV may be large.

Last, third signals transmitted through the third test path, which passes through the TSVs, are output as test results. The test circuit analyzes the test results to measure setup times in operation S14.

Thereafter, analysis results with respect to the test results output through the first through third test paths are compared in operation S15, and RC characteristics of the TSVs are determined according to the comparison result in operation S16. For example, differences between the setup times of the first signals of the TSVs and the setup times of the second signals of the TSVs are compared to determine characteristics associated with capacitance components of the TSVs, and if a variation in the setup time of the first signal of a particular TSV and a variation in the setup time of the second signal of the particular TSV are larger than an average variation of other TSVs, it can be determined that a capacitance component of the particular TSV is large. In the same way, differences between the setup times of the first signals of the TSVs and the setup times of the third signals of the TSVs are compared to determine characteristics associated with resistance components of the TSVs. If a variation in the setup time of the first signal of a particular TSV and a variation in the setup time of the third signal of the particular TSV are larger than an average variation of other TSVs, it can be determined that a resistance component of the particular TSV is large.

FIG. 17 is a block diagram of a test system according to an embodiment of the present general inventive concept. A test of a semiconductor chip (or a semiconductor product) is a final stage of semiconductor chip production for determining a pass or fail of the semiconductor chip. Referring to FIG. 17, a test system 4000 may include a tester board 4100 and a tester 4200. It is assumed that a semiconductor device to be tested according to an embodiment of the present general inventive concept is a memory chip or a memory device.

The test board 4100 may include a socket 4110 on which a memory device 4111 is mounted, a clock pin CLK to transmit a clock signal, an address pin Ai to transmit an address signal, where i is an integer from 0 to n, a control pin CONTROL to transmit control signals RAS, CAS, WE, CKE, CS, DQM, DQS, and data input/output pins DQ0 through DQn.

The memory device 4111 to be tested is installed (or inserted) in the tester board 4110. The memory device 4111 may be an ×16 or ×32 semiconductor chip, and transmit and receive signals such as a clock signal, an address, a control signal, and data with the tester 4200 through various pins of the tester board 4100.

The tester 4200 provides the test signal described in the foregoing embodiments to the memory device 4111 through the tester board 4110, and the test signal is transmitted through multiple test paths in the memory device 4111. The signal transmitted through the multiple test paths is provided as test results to the tester 4200. The tester 4200 then measures a setup time of the signal for each test path and compares the measured setup times for the multiple test paths, thus determining RC characteristics of the TSVs.

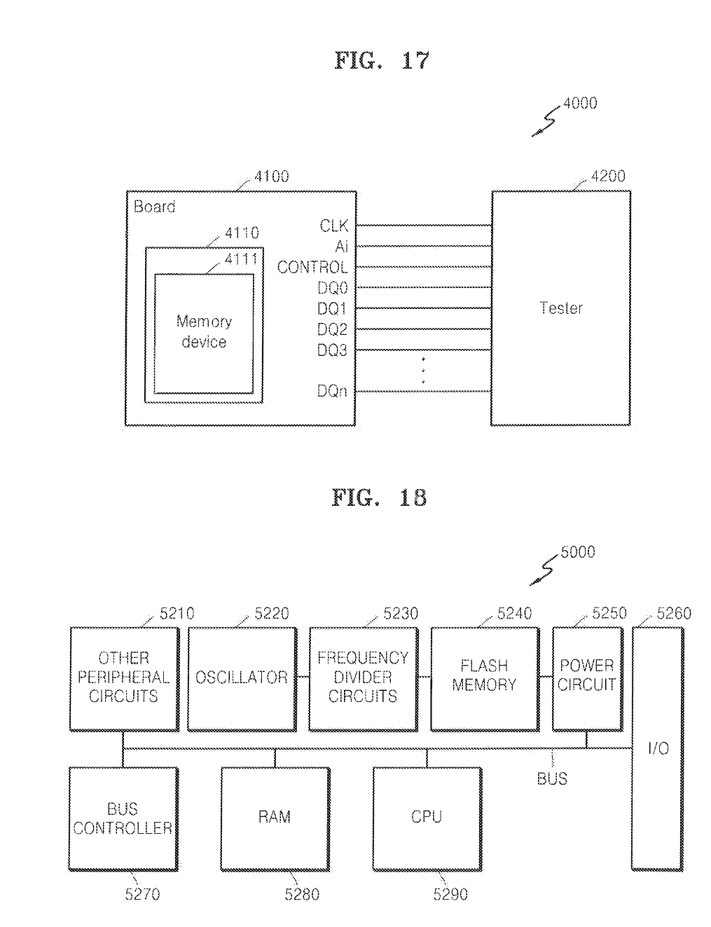

FIG. 18 is a block diagram of an application example of a single-chip micro computer including a semiconductor memory device of a stacked structure according to the present general inventive concept.

Referring to FIG. 18, a microcomputer 5000 in the form of a circuit module may include a central processing unit (CPU) 5290, a memory device, e.g., a random access memory (RAM) 5280 of a stacked structure, which is used as a work area of the CPU 5290, a bus controller 5270, an oscillator 5220, a frequency divider 5230, a flash memory 5240, a power circuit 5250, an input/output port 5260, and other peripheral circuits 5210 including a timer counter and so forth. Those components are connected to an internal bus.

The CPU 5290 includes a command control part (not shown) and an execution part (not shown). The CPU 5290 decodes a fetched command through the command control part and performs a processing operation based on the decoding result through the execution part.

The flash memory 5240 stores not only an operation program or data of the CPU 5290, but also various types of data. The power circuit 5250 generates a high voltage necessary for an erase operation and a write operation with respect to the flash memory 5240.

The frequency divider 5230 divides a source frequency provided from the oscillator 5220 into a plurality of frequencies and provides reference clock signals and other internal clock signals.

The internal bus may include an address bus, a data bus, and a control bus.

The bus controller 5270 controls a bus access for a predetermined number of cycles in response to an access request from the CPU 5290. Herein, the number of access cycles is associated with a wait state and a bus width corresponding to an accessed address.

When the microcomputer 5000 is mounted on a system, the CPU 5290 controls an erase operation and a write operation with respect to the flash memory 5240. In a test or manufacturing stage of a device, the erase and write operations with respect to the flash memory 5240 may be directly controlled by an external recording device via the input/output port 5260.

One or more semiconductor devices, e.g., the flash memory 5240 or the RAM 5280, mounted on the microcomputer 5000, each may include multiple semiconductor layers, and multiple TSVs to transmit signals between the multiple semiconductor layers. In the manufacturing stage of the semiconductor device, a test operation with respect to the TSVs may be performed. The test operation with respect to the TSVs may be performed in the same manner as or similar manner to the foregoing embodiments of the present general inventive concept.

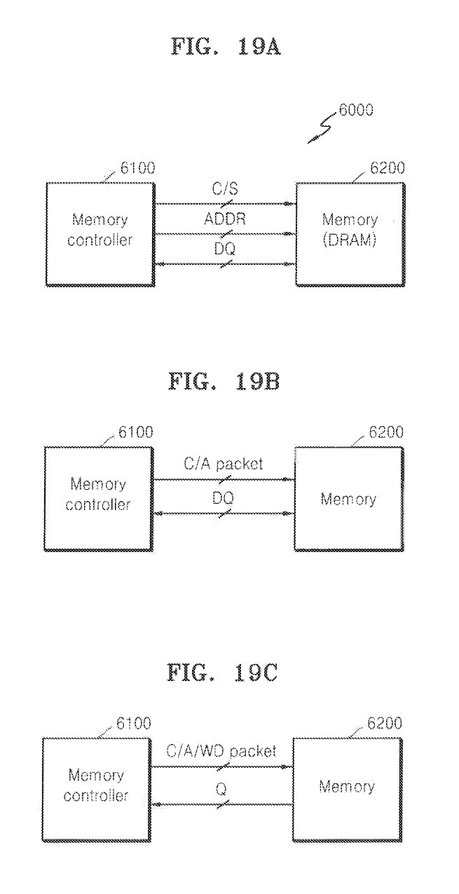

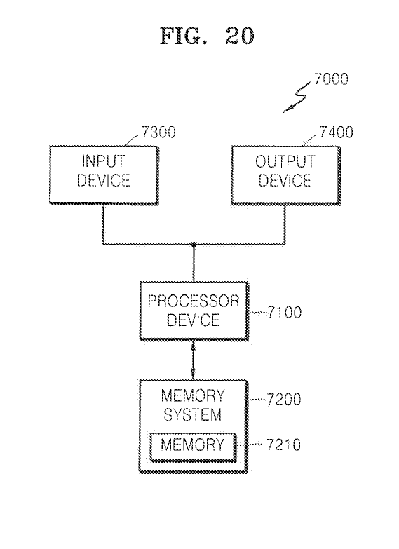

FIGS. 19A through 19C are block diagrams for illustrating an example of signal transmission of a memory controller and a memory device in a semiconductor memory system according to an embodiment of the inventive concept.

Referring to FIG. 19A, a bus protocol between a memory controller 6100 and a memory device 6200 in a semiconductor memory system 6000 is shown, and a control signal C/S, such as /CS, CKE, /RAS, /CAS, /WE, etc., and an address signal ADDR are provided from the memory controller 6100 to the memory device 6200. Data DQ is transmitted bi-directionally. Referring to FIG. 19B, packetized control signals and address signals C/A Packet are provided from the memory controller 6100 to the memory 6200 and the data DQ is transmitted bi-directionally. Referring to FIG. 19C, packetized control signals, address signals, and write signals (C/A/WD packet) are provided from the memory controller 6100 to the memory 6200 and a data output Q is transmitted unidirectionally from the memory 6200 to the memory controller 6100. The memory controller 6100 or the memory device 6200 may include a plurality of semiconductor layers and TSVs, and in a manufacturing stage thereof, the foregoing embodiments of the present general inventive concept may be used to test RC characteristics of the TSVs.

FIG. 20 is a block diagram of an application example of an electronic system including a semiconductor memory device of a stacked structure according to the present general inventive concept.

Referring to FIG. 20, an electronic system 7000 may include an input device 7300, an output device 7400, a memory system 7200, and a processor deice 7100.

The memory system 7200 may include a memory device 7210 of a stacked structure and a memory controller (not shown) to control the memory device 7210.

The processor device 7100 controls an overall operation of the electronic system 7000 by interfacing with the input device 7300, the output device 7400, and the memory system 7200. The memory controller (not shown) or the memory device 7210 provided in the memory system 7200 may include a plurality of semiconductor layers and TSVs, and to test RC characteristics of the TSVs at a stage for manufacturing the memory controller (not shown) or the memory device 7210, the above-described embodiments of the present general inventive concept may be used.

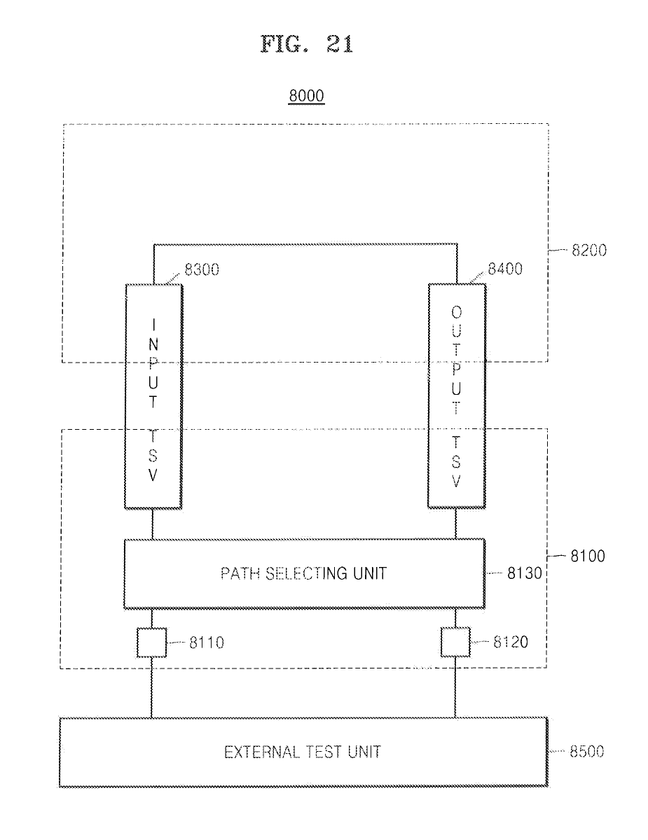

FIG. 21 is a block diagram of a semiconductor device 8000 according to an exemplary embodiment of the present general inventive concept. The semiconductor device 8000 includes a first semiconductor layer 8100 and a second semiconductor layer 8200. The first semiconductor layer 8100 and the second semiconductor layer 8200 are connected by an input TSV 8300 and an output TSV 8400. The output TSV 8400 may be plural in number. The first semiconductor layer 8100 includes an input pad 8110 and 8120. The input pad 8110 may receive a test signal from an external test unit 8500, and the output pad 8120 may output the test signal to the external test unit 8500. The first semiconductor layer 8100 includes a path selecting unit 8130. The path selecting unit 8130 may select a path to transmit the test signal from the input pad 8110 to the output pad 8120. The path selecting unit 8130 may select a path that is electrically insulated from the input TSV 8300. The path selecting unit 8130 may also select a path that is electrically connected to the input TSV 8300. The path that is electrically connected to the input TSV 8300 may be a path that is through the input TSV 8300 or a path that is not through the input TSV 8300. By measuring and analyzing test signals that are transmitted through the different paths, It is possible to measure the RC characteristics of the input TSV 8300. The test signals may be measured and analyzed by the external test unit 8500 or may be measured a test unit included in the semiconductor device 8000.

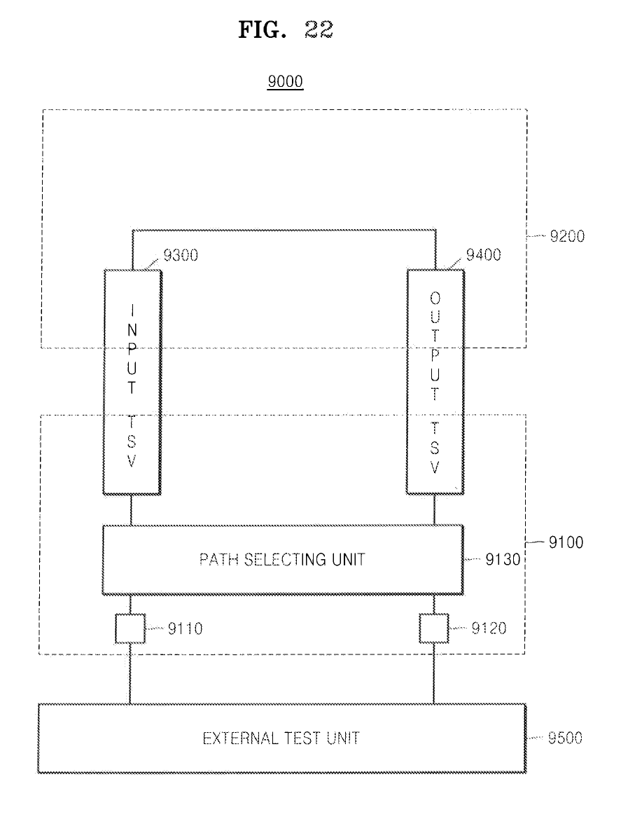

FIG. 22 is a block diagram of a semiconductor device 9000 according to an exemplary embodiment of the present general inventive concept. The semiconductor device 9000 includes a first semiconductor layer 9100 and a second semiconductor layer 9200. The first semiconductor layer 9100 and the second semiconductor layer 9200 are connected by an input TSV 9300 and an output TSV 9400. The input TSV 9300 may be plural in number. The first semiconductor layer 9100 includes an input pad 9110 and 9120. The input pad 9110 may receive a test signal from an external test unit 9500, and the output pad 9120 may output the test signal to the external test unit 9500. The first semiconductor layer 9100 includes a path selecting unit 9130. The path selecting unit 9130 may select a path to transmit the test signal from the input pad 9110 to the output pad 9120. The path selecting unit 9130 may select a path that is electrically insulated from the output TSV 9400. The path selecting unit 9130 may also select a path that is electrically connected to the output TSV 9400. The path that is electrically connected to the output TSV 9400 may be a path that is through the output TSV 9400 or a path that is not through the output TSV 9400. By measuring and analyzing test signals that are transmitted through the different paths, it is possible to measure the RC characteristics of the output TSV 9400. The test signals may be measured and analyzed by the external test unit 9500 or may be measured a test unit included in the semiconductor device 9000.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor device comprising:
a first semiconductor layer;
one or more second semiconductor layers stacked on the first semiconductor layer; and
a plurality of input through-silicon-vias (TSVs) to transmit signals from a plurality of input pads, respectively,
wherein in a test mode, a test signal from the plurality of input pads is transmitted through at least two test paths, and the test signal transmitted through each of the test paths is output as a test result with respect to each of the plurality of input TSVs through an output pad.

2. The semiconductor device of claim 1, wherein the at least two test paths comprise:
a first test path formed in the first semiconductor layer and electrically insulated from the input TSVs; and
a second test path formed in the first semiconductor layer and electrically connected with the input TSVs through at least one node.

3. The semiconductor device of claim 2, wherein the first semiconductor layer comprises:
a path selecting unit to receive a first signal and a second signal through the first test path and the second test path, respectively, and to selectively output one of the first signal and the second signal; and
a first storing unit to receive and store the output of the path selecting unit,
wherein the path selecting unit and the first storing unit are disposed to correspond to each of the plurality of input TSVs.

4. The semiconductor device of claim 3, wherein during a first period, the path selecting unit selectively outputs the first signal and the first storing unit stores the first signal and outputs the first signal as the test result, and
during a second period, the path selecting unit selectively outputs the second signal and the first storing unit stores the second signal and outputs the second signal as the test result.

5. The semiconductor device of claim 3, wherein the at least two test paths further comprises a third test path to transmit the test signal through the input TSV.

6. The semiconductor device of claim 5, wherein the second semiconductor layer comprises a second storing unit to receive a third signal transmitted through the third test path and to store the third signal, and the second storing unit is disposed to correspond each of the plurality of input TSVs.

7. The semiconductor device of claim 6, wherein after the first signal and the second signal are output as the test results, the third signal is output as the test result.

8. The semiconductor device of claim 6, wherein at least one of the first storing unit and the second storing unit comprises:
a multiplexer comprising a first input end to receive a signal from one of the first through third test paths corresponding to an ath TSV and a second input end to receive a test result with respect to an (a−1)th TSV; and
a latch to store an output of the multiplexer,
wherein a is an integer greater than 2.

9. The semiconductor device of claim 8, wherein at least one of the first storing unit and the second storing unit sequentially outputs a test result with respect to each of the plurality of input TSVs through the output pad bit-by-bit.

10. A semiconductor device comprising:
a first semiconductor layer;
one or more second semiconductor layers stacked on the first semiconductor layer; and
a plurality of output through-silicon-vias (TSVs) to transmit signals through a plurality of output pads, respectively,
wherein in a test mode, a test signal from a plurality of input pads is transmitted through at least two test paths, and the test signal transmitted through each of the test paths is output as a test result with respect to each of the plurality of output TSVs through the plurality of output pads.

11. The semiconductor device of claim 10, wherein the at least two test paths comprise:
a first test path formed in the first semiconductor layer and electrically insulated from the output TSVs; and
a second test path formed in the first semiconductor layer and electrically connected with the output TSVs through at least one node.

12. The semiconductor device of claim 11, wherein the first semiconductor layer comprises:
a path selecting unit to receive a first signal and a second signal through the first test path and the second test path and to selectively transmit the received first signal and the received second signal to the output pads,
wherein the path selecting unit is disposed to correspond to each of the plurality of output TSVs.

13. The semiconductor device of claim 12, wherein the at least two test paths further comprise a third test path to transmit the test signal through the output TSVs.

14. The semiconductor device of claim 13, wherein the second semiconductor layer comprises a first output control unit disposed on the third test path and to control application of a third signal, transmitted through the third test path, to the output TSVs.

15. The semiconductor device of claim 14, wherein the path selecting unit further receives a third signal, transmitted through the third test path, and selectively transmits the received third signal to the output pads.

16. A semiconductor device comprising:
a first semiconductor layer including an input pad to receive a test signal and an output pad to output the test signal;
a second semiconductor layer connected to the first semiconductor layer by at least one through-silicon-via (TSV); and
a path selecting unit to select at least one of a plurality of paths to transmit the test signal from the input pad to the output pad, wherein the plurality of paths include at least one path electrically insulated from the at least one TSV and at least one path electrically connected to the at least one TSV.

17. The semiconductor device of claim 16, wherein the at least one path electrically connected to the at least one TSV comprises:
at least one path through the at least one TSV; and
at least one path that is not through the at least one TSV.

18. The semiconductor device of claim 16, wherein the at least one TSV comprises:
an input TSV to transmit the test signal from the first semiconductor layer to the second semiconductor layer; and
a plurality of output TSVs to transmit the test signal from the second semiconductor layer to the first semiconductor layer.

19. The semiconductor device of claim 16, wherein the at least one TSV comprises:
a plurality of input TSVs to transmit the test signal from the first semiconductor layer to the second semiconductor layer; and
an output TSV to transmit the test signal from the second semiconductor layer to the first semiconductor layer.

20. The semiconductor device of claim 16, wherein the input pad receives the test signal from an external test unit and the output pad outputs the test signal to the external test unit.
